(19) United States
(12) Patent Application Publication
(10) Pub. No.: US 2001/0035766 A1
(43) Pub. Date: Nov. 1, 2001

(54) IC test device and method

(76) Inventor: Minoru Nakajima, Tokyo (JP)

Correspondence Address: BURNS DOANE SWECKER & MATHIS L L P, POST OFFICE BOX 1404, ALEXANDRIA, VA, 22313-1404, US

(21) Appl. No.: 09/842,131

(22) Filed: Apr. 26, 2001

(30) Foreign Application Priority Data
Apr. 27, 2000 (JP) 2000-128317

(51) Int. Cl. G01R 31/26

(52) U.S. Cl. 324/765

(57) ABSTRACT

An IC test device and method are provided which can display the results of a SHMOO plot accurately by performing decisions only for the necessary portions thereof, thus shortening the time required for performing data acquisition. A test point separation section groups the test points within the testing range for the SHMOO plot into blocks. A control section performs pass/fail decisions via a testing section for test points at the vertices of the blocks, and, from the patterns of decision results, picks out those blocks for which the test results for adjacent vertices are different, and picks out as complete testing blocks for which is to be tested at all the test points included in them, those blocks which have in common an edge region which includes vertices for which the test results differ. The testing section performs pass/fail decisions for all the test points within the complete testing blocks.

### BACKGROUND OF THE INVENTION

1. Field of the Invention

The present invention relates to a test method when making a SHMOO plot with an IC (integrated circuit) test device, and to an IC test device which implements the method.

2. Description of the Related Art

The so called process of SHMOO plotting is one in which testing is performed upon an IC which is to be the subject of testing (hereinafter, simply termed “the IC”), while varying the values input to the IC of a plurality of parameters through a number of combinations thereof, and the results of these tests are displayed as a plot.

For example, in the case that these parameters for combinations of various values of which testing is to be performed are the power source voltage and the operational frequency (so that, for example, a SHMOO plot is to be displayed upon a two dimensional plane in which the value of the power source voltage is plotted along the X axis direction while the value of the operational frequency is plotted along the Y axis direction), then testing of the IC is performed using various combinations of power source voltage values and operation frequency values while varying these parameters each time by respective predetermined intervals, each of these combinations corresponding to a test point in the plot, and for each test a decision is made as to whether or not the IC is operating properly for these values of the parameters.

In other words, portions of the testing range of combinations of power source voltage values and frequency values where the IC operates correctly are examined based on the test results over the two dimensional plane.

The method of testing the IC over all the combinations of power source voltage and operational frequency value (in concrete terms, varying the values of all the parameters in turn through pluralities of test values which are set in advance) and displaying the respective decision results is one representative such testing method (hereinafter termed the first testing method).

Further, the method of testing the IC by, among all the test points which correspond to all the combinations of power source voltage and operational frequency value, only making decisions at certain ones of these test points which have been selected at a predetermined set interval, and, if there is a change in the decision results for these test points, only displaying the decision results for those test points which are located between the test points at which the results are different, is another representative such testing method (hereinafter termed the second testing method).

However, with the SHMOO plotting process using the first testing method described above in which all the test results for all the combinations of the parameters are displayed, there is the deficiency that the assessment of the operational characteristics of the IC is slow, since a relatively long period of time is required for acquisition of the data.

Further, with the SHMOO plotting process using the second testing method described above in which the decision results are displayed at predetermined intervals, there is the problem that it may not be possible to perform accurate assessment using the SHMOO plot, since, even if test points where the decision result changes exist between two of the test points at which decisions were taken, these test points are not taken as objects of testing.

### SUMMARY OF THE INVENTION

The present invention has been made in the light of the above problems, and proposes an IC test device and an IC test method, which are capable of performing data acquisition in a short time period, and moreover of displaying results in an accurate SHMOO plot by performing decisions only over necessary portions of the parameter space.

According to the device aspect of the present invention, there is provided an IC test device, comprising: a block grouping section which divides test points within a testing range of a SHMOO plot which is made up from combinations of parameters utilized for IC testing into a plurality of blocks; a testing section which performs pass/fail decisions for designated test points; a block pick out section which, along with causing pass/fail decisions to be performed by the testing section for the test points which correspond to the vertices of the blocks, picks out those blocks for which the test results vary between the vertices as complete testing blocks for which testing is to be done at all the test points included in them, based upon patterns of test results which have been obtained by the decisions, and moreover picks out blocks which have in common an edge region which includes vertices for which the test results differ as complete testing blocks, and causes pass/fail decisions to be performed by the testing section for all the test points within the complete testing blocks; and: a SHMOO plot production section which produces the SHMOO plot based upon results of pass/fail decisions performed by the testing section.

Further, according to the method aspect of the present invention, there is proposed an IC test method, comprising the steps of: a block grouping step, which divides test points within a testing range of a SHMOO plot which is made up from combinations of parameters utilized for IC testing into a plurality of blocks; a first picking out step, which performs pass/fail decisions for the test points which correspond to the vertices of the blocks, and picks out those blocks for which the test results vary between the vertices as complete testing blocks for which testing is to be done at all the test points included in them, based upon patterns of test results which have been obtained by the decisions; a second picking out step, which picks out blocks which have in common an edge region which includes vertices for which the test results differ as complete testing blocks; a decision step, which performs pass/fail decisions for all the test points in the complete testing blocks; and: a SHMOO plot production step, which produces the SHMOO plot based upon the pass/fail decision results.

In this manner, according to the present invention, when assessing the characteristics of an IC, the test points in the test range of the SHMOO plot are grouped into blocks, testing is performed at the vertices of these blocks only, and the SHMOO plot is produced by picking out those blocks for which testing is to be performed at all the points within them. Due to this, since the test point boundary between pass decisions and fail decisions is accurately determined even though testing is not performed for all of the test points which lie within the testing range of the SHMOO plot, therefore the time period which is required for making the pass/fail decisions is considerably reduced, and the beneficial result is obtained of enhancing the efficiency of IC production.

### BRIEF DESCRIPTION OF THE DRAWINGS

FIG. 1 is a block diagram showing the structure of an IC test device according to the preferred embodiment of the present invention;

FIG. 2 is a flow chart showing an example of the operation of this IC test device according to the preferred embodiment of the present invention;

FIG. 3 is a general figure for explanation of the formation into blocks of test points within the test range of a SHMOO plot;

FIG. 4 is a general figure showing the relationship between a subject block and the adjacent blocks above and below it and to its left and right;

FIGS. 5 and 6 are figures showing the respective arrangements of patterns #1 and #2, in both which there is no variation, along any of their edge regions, between the test results at their vertices M1 through M4;

FIGS. 7 through 14 are figures showing the respective arrangements of patterns #3 through #10, which are rectangular regions with vertices M1 through M4 at just one of which the test result is different from those at the other three, so that they each have just two edge regions along which the test results for the adjacent vertices at the ends are different;

FIGS. 15 through 18 are figures showing the respective arrangements of patterns #11 through #14, which are rectangular regions with vertices M1 through M4 at two ones of which the test results are different from those at the other two, so that they each have just two edge regions along which the test results for the adjacent vertices at the ends are different;

FIGS. 19 and 20 are figures showing the respective arrangements of patterns #15 through #16, which are rectangular regions with vertices M1 through M4 at two ones of which the test results are different from those at the other two, so that along all four edge regions of each of them the test results for the adjacent vertices at the ends are different;

FIG. 21 is an explanatory figure showing a situation when, according to the preferred embodiment of the present invention, the test range for the SHMOO plot has been divided up into blocks, along with the vertices of each of the blocks;

FIG. 22 is an explanatory figure showing decision results when, according to the preferred embodiment of the present invention, over the test range of the SHMOO plot, testing has been performed over certain complete testing blocks for which testing must be performed at every test point in the block;

FIG. 23 is an explanatory figure showing decision results when, according to the preferred embodiment of the present invention, testing has been performed at all the test points in the blocks for which edge regions exist which have test points at which the test results differ from those at other adjacent test points;

FIG. 24 is an explanatory figure showing decision results when, according to the preferred embodiment of the present invention, testing has been performed at all the test points in certain complete testing blocks which have been newly picked out as a result of the test for the blocks described above;

FIG. 25 is an explanatory figure showing test results, according to the preferred embodiment of the present invention, for the SHMOO plot which is finally outputted; and:

FIG. 26 is an explanatory figure showing, according to the preferred embodiment of the present invention, a situation when, as a result of grouping into blocks over the test range for the SHMOO plot, the test results at the vertices of each block are the same, for all the blocks within the test range for the SHMOO plot, so that then the position of the vertices has been shifted and the grouping into blocks has been performed again.

### DETAILED DESCRIPTION OF THE PREFERRED EMBODIMENT

In the following, the preferred embodiment of the present invention will be explained in detail with reference to the figures.

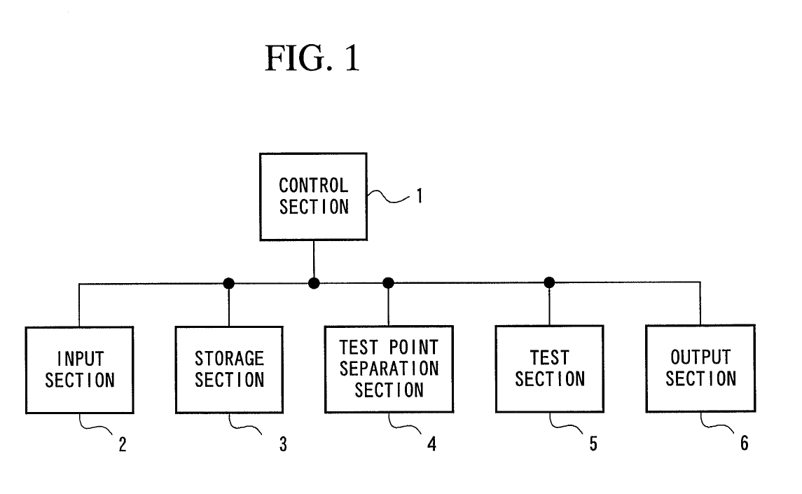

FIG. 1 is a block diagram showing the structure of an IC test device according to the preferred embodiment of the present invention. Referring to this figure, a control section 1 comprises at least a CPU (central processing unit) and a memory, and it controls circuits in the IC test device and performs tests upon an IC (not shown in the figures), according to a testing program which is stored in a storage section 3. An input section 2 inputs control signals from an input device such as a keyboard, a mouse, or the like to the control section 1.

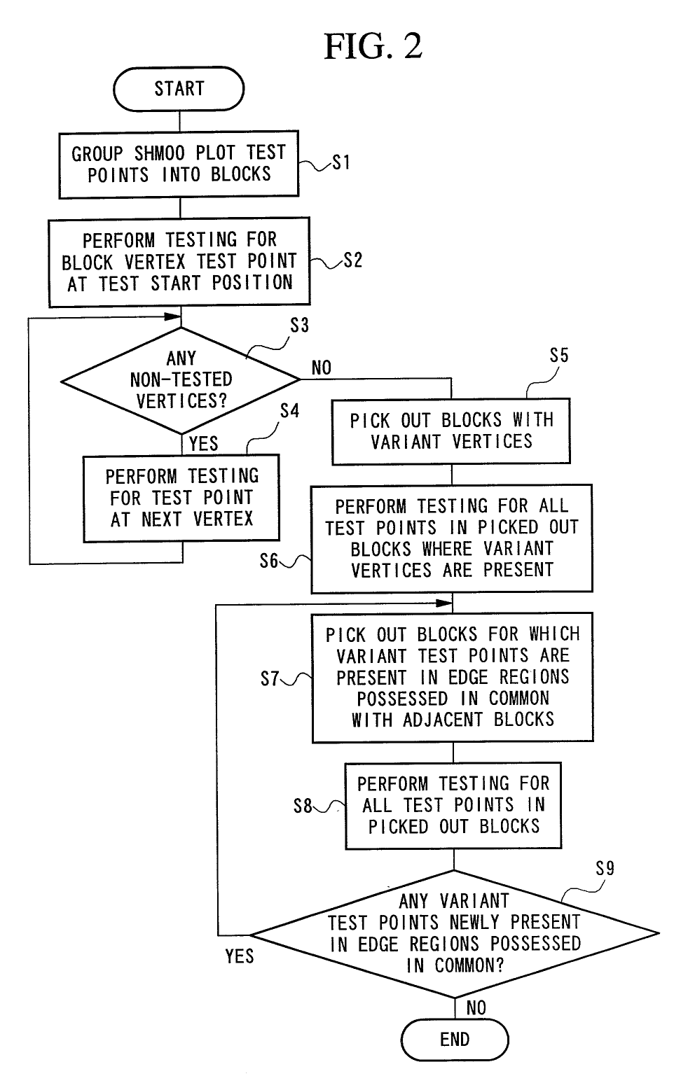

A testing program which executes the processing shown in the flow chart of FIG. 2 is stored in the storage section 3. The control section 1 performs testing processing for various operational characteristics of an IC by following this flow chart.

In detail, the control section 1 performs control of the operations of the input section 2, of a test point separation section 4, of a test section 5, and of an output section 6, according to the abovementioned testing program. The operations described in the following explanation which are performed by the input section 2, the test point separation section 4, the test section 5, and the output section 6 are executed under control of the control section 1 according to the abovementioned control program, in order to perform IC testing.

With regard to the way in which this testing processing operates, although this will be explained in detail hereinafter with respect to an operational example, when the flow of the IC testing operation according to the present invention is understood in the broad sense, it may be considered as comprising the following stages (1) through (9):

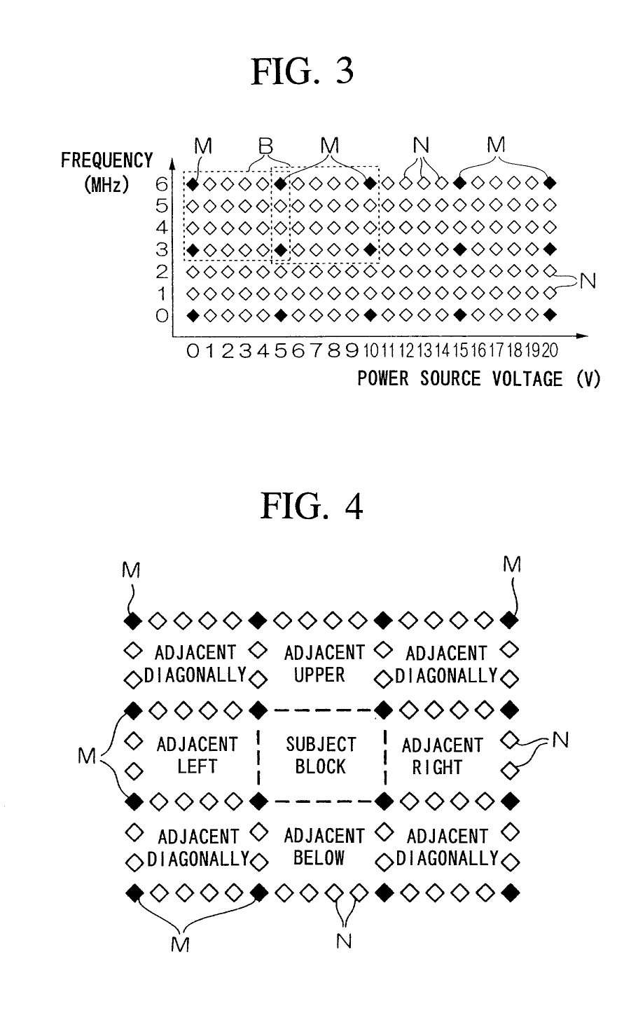

(1) As shown in FIG. 3, over the range of combinations of parameter values which make up the SHMOO plot (for example, combinations of various values of power source voltage and operational frequency), the test points N in this range which are shown by rhomboid shapes are grouped together to form blocks B. At this time, the special test points N at the four comers of the blocks B constitute its vertices M (shown in the figure by black rhombuses).

(2) Over the test range for each of the parameters in the above described SHMOO plot, testing of the operation of the IC is performed under the conditions specified by the combination of parameters at each of the vertices M of each of the blocks. In other words, in this case, testing (pass/fail decision) is not performed for the test points which are shown in FIG. 3 by the white rhombuses, while testing (pass/fail decision) is only performed for the test points which are shown in FIG. 3 by the black rhombuses. And, the operation of testing the IC consists of, while varying the values of the parameters, making decisions as to whether or not the IC which is being tested is operating normally, in other words of making pass (normal operation)/fail (abnormal operation) decisions, for each combination among the combinations of values of the various parameters (the test points N).

(3) As shown in FIG. 4, the operation is performed of picking out the subject block and certain blocks adjacent to it above it, below it, and to its left and its right (i.e., adjacent upper, adjacent below, adjacent right, and adjacent left) as “complete testing blocks”. Here, the term “complete testing block” means a block for which testing is to be performed at all the test points N other than the vertices M.

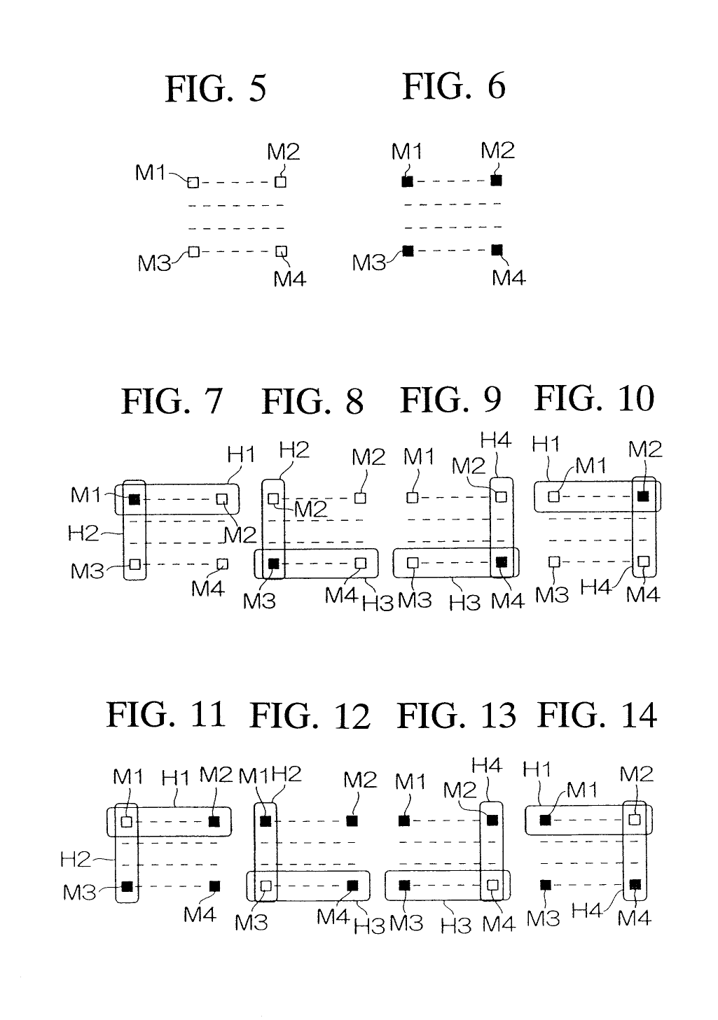

At this time, the pattern of the test results at the four vertices of the subject block is compared with the patterns #1 through #16 which are shown in FIGS. 5 through 20, and the one of these patterns #1 through #16 which matches with the pattern of the test results at the vertices of the subject block is derived. It should be noted that in FIGS. 5 through 20 the white squares denote pass decisions, while the black squares denote fail decisions.

For example, if it is supposed that the subject block of FIG. 4 has a pattern of test values which is matched by the pattern #3 of test values shown in FIG. 7, then the edge region H1 of the subject block along its upper side and the edge region H2 of the subject block along its left side each includes end vertices which, in the subject block, constitute adjacent vertices for which the decision results are different (i.e., between which the decision result has changed).

By doing this, the subject block, the adjacent block above this subject block which has the edge region H1 in common with this subject block, and the adjacent block to the left of this subject block which has the edge region H2 in common with this subject block, are picked out as complete testing blocks for which testing is to be performed at all the test points N within them.

(4) Testing is performed for all the test points N in the complete testing blocks which have been picked out in stage (3).

(5) Next, for each of the upper, lower, and left and right edge regions of each of the blocks, if in this edge region there exists a test point N (including the vertices M of the block) for which the test result is different from those at other test points N to which this test point N is adjacent, in other words, if in this edge region there exists some test point N at which the test result is a pass while the test result at another test point N which is adjacent to this test point N is a fail, the block which has this edge region which includes these test points mutually in common therewith is picked out as another block for which testing is to be performed at all of the test points N within it (i.e. as another complete testing block).

(6) Testing is performed for all the test points N in the complete testing blocks which have been picked out in stage (5).

(7) The stages (5) and (6) are repeated until no further edge regions are detected, among the edge regions at the upper sides, the lower sides, and the left and right sides of each block, in which there is present any test point N (other than the vertices M) at which the test result is different from the test result at another adjacent test point N.

(8) From among all the test points N at which testing has been performed as described above, only those test points N which are understood as constituting the boundary where the test result changes, and the vertices M, are output as the SHMOO plot. Here, pairs of mutually adjacent test points which consist of a test point N at which a pass decision has been made and a test point N at which a fail decision has been made are considered to be the test points N which constitute the boundary where the test result changes, i.e. which constitute the boundary between the region in which the test results for the test points N are fail decisions and the region in which the test results for the test points N are pass decisions.

(9) The range for defining the blocks is shifted, and the processing described above in the stages (2) through (8) is started again, and this processing is repeated when, over all of the blocks in the testing range for the SHMOO plot, the patterns of the test results for the vertices M of each of the blocks comes to match in the stage (3) either with the pattern #1 shown in FIG. 5 or with the pattern #2 shown in FIG. 6.

In the following, the structural elements of an IC test device according to the preferred embodiment of the present invention will be explained in line with the summary of the various testing operations set out under the above stages (1) through (8).

The test point separation section 4 divides the combinations of setting values of the plurality of parameters for performing the tests which are required for making up the SHMOO plot into blocks which are composed of predetermined testing regions.

For example, if as shown in FIG. 3 the plotting interval along the X axis (the voltage value of the power source voltage) is set to 5, and the plotting interval (the operational frequency) along the Y axis is set to 3, then the test range for the SHMOO plot is divided into the shown blocks.

Here, the points shown as rhombuses are test points N, each of which is a combination of set values of the various parameters. Each test point N (including the vertices M) is a point of testing with a combination of parameters which are within the power source voltage range of 0V to 20V and the operational frequency range of 0 MHz to 6 MHz, such as for example, power source voltage 0V and operational frequency 0 MHz, power source voltage 5V and operational frequency 1 MHz, power source voltage 16 V and operational frequency 5 MHz, etc. Here, over the setting range for each parameter for the SHMOO plot, the power source voltage is varied in steps of 1V while the operation frequency is varied in steps of 1 MHz, and thereby the test points N are established as combinations of these parameters.

In this way, the resolution along the X axis for test of the voltage value of the power source voltage is set in advance in the storage section 3 in the testing program, for example in steps of 1V; or, for example, steps of 0.5V would also be acceptable, etc. In the same manner, the resolution along the Y axis for test of the operation frequency is set in advance in the storage section 3 in the testing program, for example in steps of 1 MHz; or, for example, steps of 0.5 MHz would also be acceptable, etc. However, it would also be possible for these resolutions to be set via the input section 2 from outside the IC test device.

In FIG. 3, the regions B formed by linking the vertices M which are the black rhombuses will be taken as block units. In other words, the black rhombuses constitute the vertices M of each block. Thus, each block has peripheral edge regions in common with other adjacent blocks (the edge regions H1 through H4 in subsequent figures), which are constituted by the sets of test points N which lie upon the straight lines joining its vertices M.

The test section 5 is the portion of the device which performs tests upon an IC, and it performs control for setting the numerical value of each parameter for testing according to control signals from the control section 1. For example, the test section 5 performs control for setting the combinations of parameters provided to the IC, like fixing the value of the frequency upon the Y axis and varying the power source voltage value along the X axis in steps of 1V.

At this time, the test section 5 provides pairs of operational frequency values and power source voltage values, each of which constitutes a combination of parameters like those mentioned above, to the IC which is the subject of testing, and determines whether or not the IC is operating properly while each of these combinations of parameter values is being supplied; in other words, it makes a pass/fail decision for each parameter value combination.

This pass/fail decision results are output from the test section 5 to the control section 1 in association with its combination of parameter values, and is stored by the control section 1 in a SHMOO plot result storage section (not shown in the figures) of the storage section 3.

And, when for example the voltage value in the X axis direction has reached the end of its test range, then the test section 5 changes the frequency in the Y axis direction by the step of 1 MHz and fixes this value of the frequency upon the Y axis, and then again makes pass/fail decisions while varying the combination of parameters provided to the IC by stepping up the voltage value along the X axis direction by steps of 1V.

The SHMOO plot which shows the results of the pass/fail decisions for these combinations of power source voltage value and frequency value for the IC which is the subject of testing is constructed by repeating the above described control and by performing testing of the IC for each combination of values of the parameters.

Further, the control section 1 takes each block within the test range of the SHMOO plot, in order, as a subject block, and, for each of these subject blocks, compares the pattern for its vertices M defined by the test results with each of the patterns shown in FIGS. 5 through 20, and determines which of these patterns agrees with the pattern defined by the test results at the vertices M of the subject block.

And, furthermore, when the control section 1 is detecting which one from among the various patterns of FIGS. 5 through 20 agrees with the pattern of the vertices M of the subject block, it picks out each of its edge regions which includes two adjacent vertices which have different decision results.

Thus, the patterns shown in FIGS. 5 through 20 correspond to patterns of pass/fail decision results at the vertices M of each of the blocks which have been obtained by grouping into blocks the test points within the test range of the SHMOO plot, and they are patterns which are set in advance for the pass/fail decision results.

Among these patterns set in advance, the pattern #1 shown in FIG. 5 and the pattern #2 shown in FIG. 6 are patterns in which all of the test results for the vertices Ml through M4 of the edge regions are the same.

And a block, the pattern of whose vertices M agrees with either of these patterns #1 or #2, is not picked out as a complete testing block (in other words, as a block for which testing at all of the test points N within the block is to be performed). Each of the patterns explained below is stored in the storage section 3, and the control section 1 reads them each out one by one for comparison.

Further, the patterns #3 through #10 which are shown in FIGS. 7 through 14 are patterns in which, among the test results for each of the vertices M1 through M4 of their edge regions, the test result for one of these vertices is different from the test results for the other three vertices, so that in each of these patterns there are just two edge regions for which the test results for adjacent vertices are different.

In the pattern #3 shown in FIG. 7, the result at the vertex M1 is a fail decision while the results at the other three vertices M2, M3, and M4 are all pass decisions, and, if the pattern of the test results at the vertices M of the subject block agrees with this pattern #3, then this subject block, and the blocks which have in common with this subject block the edge region H1 and the edge region H2, become the objects of being picked out.

In the pattern #4 shown in FIG. 8, the result at the vertex M3 is a fail decision while the results at the other three vertices M1, M2, and M4 are all pass decisions, and, if the pattern of the test results at the vertices M of the subject block agrees with this pattern #4, then this subject block, and the blocks which have in common with this subject block the edge region H2 and the edge region H3, become the objects of being picked out.

In the pattern #5 shown in FIG. 9, the result at the vertex M4 is a fail decision while the results at the other three vertices M1, M2, and M3 are all pass decisions, and, if the pattern of the test results at the vertices M of the subject block agrees with this pattern #5, then this subject block, and the blocks which have in common with this subject block the edge region H3 and the edge region H4, become the objects of being picked out.

In the pattern #6 shown in FIG. 10, the result at the vertex M2 is a fail decision while the results at the other three vertices M1, M3, and M4 are all pass decisions, and, if the pattern of the test results at the vertices M of the subject block agrees with this pattern #6, then this subject block, and the blocks which have in common with this subject block the edge region H1 and the edge region H4, become the objects of being picked out.

In the pattern #7 shown in FIG. 11, the result at the vertex M1 is a pass decision while the results at the other three vertices M2, M3, and M4 are all fail decisions, and, if the pattern of the test results at the vertices M of the subject block agrees with this pattern #7, then this subject block, and the blocks which have in common with this subject block the edge region H1 and the edge region H2, become the objects of being picked out.

In the pattern #8 shown in FIG. 12, the result at the vertex M3 is a pass decision while the results at the other three vertices M1, M2, and M4 are all fail decisions, and, if the pattern of the test results at the vertices M of the subject block agrees with this pattern #8, then this subject block, and the blocks which have in common with this subject block the edge region H2 and the edge region H3, become the objects of being picked out.

In the pattern #9 shown in FIG. 13, the result at the vertex M4 is a pass decision while the results at the other three vertices M1, M2, and M3 are all fail decisions, and, if the pattern of the test results at the vertices M of the subject block agrees with this pattern #9, then this subject block, and the blocks which have in common with this subject block the edge region H3 and the edge region H4, become the objects of being picked out.

In the pattern #10 shown in FIG. 14, the result at the vertex M2 is a pass decision while the results at the other three vertices M1, M3, and M4 are all fail decisions, and, if the pattern of the test results at the vertices M of the subject block agrees with this pattern #10, then this subject block, and the blocks which have in common with this subject block the edge region H1 and the edge region H4, become the objects of being picked out.

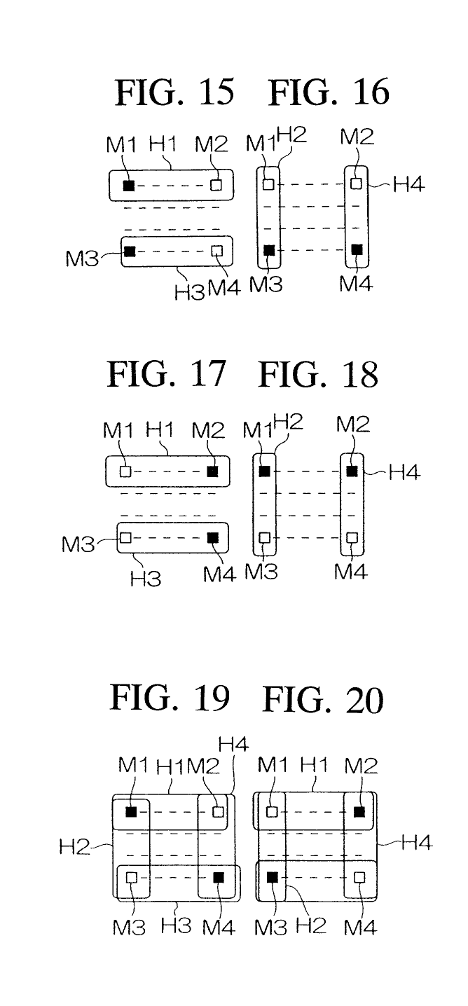

Further, the patterns #11 through #14 which are shown in FIGS. 15 through 18 are patterns in which, among the test results for each of the vertices M1 through M4 of the edge regions, the test results for two of these vertices are different from the test results for the other two vertices, and in each of which, in just two of its edge regions, the test results for adjacent vertices are different.

In the pattern #11 shown in FIG. 15, the results at the two vertices M1 and M3 are fail decisions while the results at the other two vertices M2 and M4 are pass decisions, and, if the pattern of the test results at the vertices M of the subject block agrees with this pattern #11, then this subject block, and the blocks which have in common with this subject block the edge region H1 and the edge region H3, become the objects of being picked out.

In the pattern #12 shown in FIG. 16, the results at the two vertices M3 and M4 are fail decisions while the results at the other two vertices M1 and M2 are pass decisions, and, if the pattern of the test results at the vertices M of the subject block agrees with this pattern #12, then this subject block, and the blocks which have in common with this subject block the edge region H2 and the edge region H4, become the objects of being picked out.

In the pattern #13 shown in FIG. 17, the results at the two vertices M2 and M4 are fail decisions while the results at the other two vertices M1 and M3 are pass decisions, and, if the pattern of the test results at the vertices M of the subject block agrees with this pattern #13, then this subject block, and the blocks which have in common with this subject block the edge region H1 and the edge region H3, become the objects of being picked out.

In the pattern #14 shown in FIG. 18, the results at the two vertices M1 and M2 are fail decisions while the results at the other two vertices M3 and M4 are pass decisions, and, if the pattern of the test results at the vertices M of the subject block agrees with this pattern #14, then this subject block, and the blocks which have in common with this subject block the edge region H2 and the edge region H4, become the objects of being picked out.

Further, the pattern #15 which is shown in FIG. 19 and the pattern #16 which is shown in FIG. 20 are patterns in which, among the test results for each of the vertices M1 through M4 for the edge regions, the test results for two of these vertices are different from the test results for the other two vertices, and in each of which, for all four of its edge regions, the test results for adjacent vertices are different.

In the pattern #15, the results at the two vertices M1 and M4 are fail decisions while the results at the other two vertices M2 and M3 are pass decisions, and, if the pattern of the test results at the vertices M of the subject block agrees with this pattern #15, then this subject block, and the blocks which have in common with this subject block the edge region H1, the edge region H2, the edge region H3, and the edge region H4, become the objects of being picked out.

In the pattern #16, the results at the two vertices M2 and M3 are fail decisions while the results at the other two vertices M1 and M4 are pass decisions, and, if the pattern of the test results at the vertices M of the subject block agrees with this pattern #16, then this subject block, and the blocks which have in common with this subject block the edge region H1, the edge region H2, the edge region H3, and the edge region H4, become the objects of being picked out.

And the control section 1, among all the blocks which are in the test range of the SHMOO plot, picks out the blocks (including the subject block) which have these picked out edge regions in common as complete testing blocks (i.e., as those blocks for which testing at all of the test points N within the block is to be performed).

Then, via the test section 5, the control section 1 performs testing for all the test points N within the complete testing blocks which have been picked out by the above process.

And if, among the upper, lower, left and right edge regions of each block for which testing has been performed, there is an edge region which has a test result which is different from that of another adjacent test point N (including the vertices M), in other words, if there is an edge region for which the test result for some test point N is a pass, and the test result for another test point N which is adjacent to this test point N is a fail, or vice versa, then the control section 1 picks out the block which has this edge region in common as a complete testing block (in other words, as a block for which testing is to be performed for all of the test points N within it).

Moreover, via the test section 5, the control section 1 performs testing for all the test points N within the complete testing blocks which have been picked out by the above.

As a result, after these new tests have been performed, the control section 1 finds out whether or not, among each upper, lower, left and right edge region of each block for which this testing has been performed, there exist any edge regions for which the test result for a test point N (including the vertexes M) is different from that for another adjacent test point N. When such an edge region is detected, the control section 1 picks out the block which has this edge region in common as a block for which testing must be performed for all the test points N within it, and, via the test section 5, performs testing for all the test points N within this block which has been picked out.

And, until for each edge region the test result becomes the same for each adjacent test point, the control section 1 continues to pick out the blocks which have in common edge regions with test results which differ from those for adjacent test points N, and, via the test section 5, repeatedly performs testing for all the test points N within these blocks.

And, from the SHMOO plot which has been obtained, among the test points N for which testing has been performed as explained above, the control section 1 outputs from the output section 6 as the SHMOO plot, only the test points N which are understood as constituting the boundary where the test result changes, as well as all of the vertices M. The output section 6 is a CRT (cathode ray tube) which, according to control by the control section 1, displays the SHMOO plot which has thus been generated, or is a printer which prints it out, or the like.

Next, referring to FIGS. 1 and 2, an example of the operation of the IC test device according to the preferred embodiment of the present invention will be explained. FIG. 2 is a flow chart showing this example of the operation of the IC test method according to the preferred embodiment of the present invention.

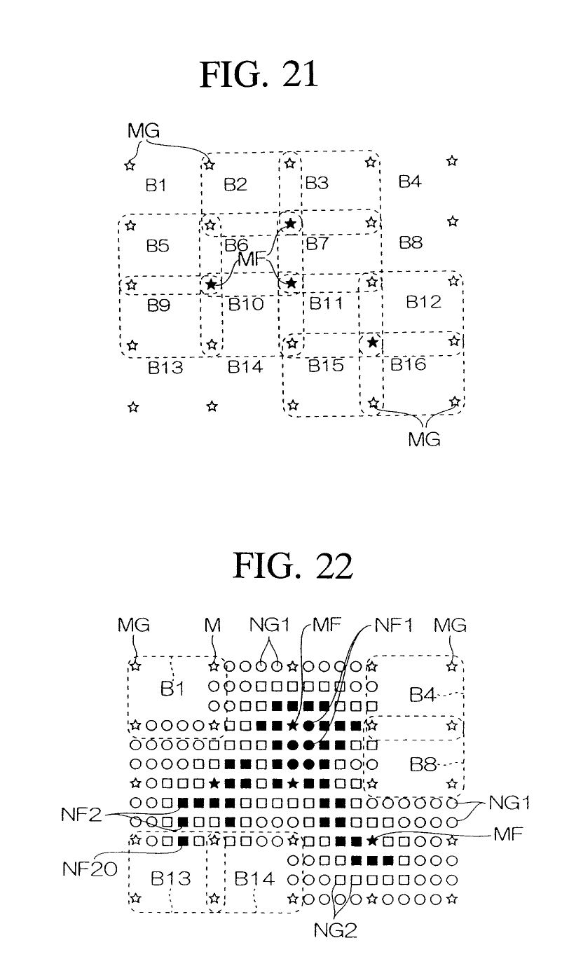

In the step S1, the test point separation section 4 groups into blocks the test points over the range of combinations of values of the parameter which make up the SHMOO plot (for example combinations of power source voltage value and frequency value), and forms the blocks from block B1 through block B16 as shown in FIG. 21.

Next, in the step S2, the control section 1 sets the test conditions for the combination of parameters which corresponds to the point at which testing is to start (for example the upper left vertex of the block B1 (shown by the star)) via the test section 5, and performs testing.

Next, in the step S3, over the test range for the SHMOO plot, the control section 1 makes a decision as to whether or not there are any vertices for which testing has not been made, and if there are any vertices which have not been tested then the flow of control continues to the step S4, while if there are no vertices which have not been tested then the flow of control is transferred to the step S5.

Next, in the step S4, over the range of the parameters described above, the control section 1 sets the testing conditions for the vertex next to the vertex which has been tested the time before via the test section 5, and performs a pass/fail decision for operation of the IC, and then the flow of control loops back to the step S3.

Here, the vertices MG (shown by the white stars) are vertices for which a pass decision has been arrived at, while the vertices MF (shown by the black stars) are vertices for which a fail decision has been arrived at. The same format is utilized in FIGS. 22 through 25 which will be referred to hereinafter, as well. It should be understood that the vertices shown by bordered white stars and also the vertices shown by black stars are collectively termed “algorithm search points”.

Next, in the step S5, the control section 1 takes each of the blocks in order from the block B1 through the block B16 as the subject block, and searches through the patterns shown in FIGS. 5 through 20 in order to find the pattern whose configuration matches the pattern of the results at the vertices of this subject block.

And the control section 1 picks out as complete testing blocks (i.e. as blocks for which testing is to be performed for all the test points within them) those subject blocks from the blocks B1 through B16 for which the decision has been made that they match any of the patterns shown in FIGS. 7 through.

Furthermore, the control section 1 picks out, from the edge regions which are included in the patterns of these complete testing blocks, those edge regions which include adjacent vertices which have different decision results, and picks out as complete testing blocks, from among the adjacent blocks above, below, and to the left and the right of the subject block, together with the subject block, those which have these edge regions in common therewith.

For example, when the block B1 is taken as the subject block, this block B1 matches with the pattern #1 which is shown in FIG. 5, and accordingly the control section 1 does not perform picking out processing for this block B1 as a complete testing block, since it has no edge region for which the decision results at its end points differ.

Further, when the block B6 is taken as the subject block, this block B6 matches with the pattern #7 which is shown in FIG. 11, and accordingly the control section 1 picks out as complete testing blocks, this block B6, and also the block B2 which is adjacent to this block B6 on its upper side which has the edge region H1 in common with it, and also the block B5 which is adjacent to this block B6 on its left side which has the edge region H2 in common with it.

By doing this, in the shown example, the control section 1 picks out the block B2, the block B3, the block B5, the block B6, the block B7, the block B9, the block B10, the block B11, the block B12, the block B15, and the block B16 as complete testing blocks. And then the flow of control in the control section 1 proceeds to the step S6.

Next, in the step S6, the control section 1 performs testing for all the test points in each of the block B2, the block B3, the block B5, the block B6, the block B7, the block B9, the block B10, the block B11, the block B12, the block B15, and the block B16 which are those blocks which have been picked out as complete testing blocks, as shown in FIG. 22; and then the flow of control continues to the step S7.

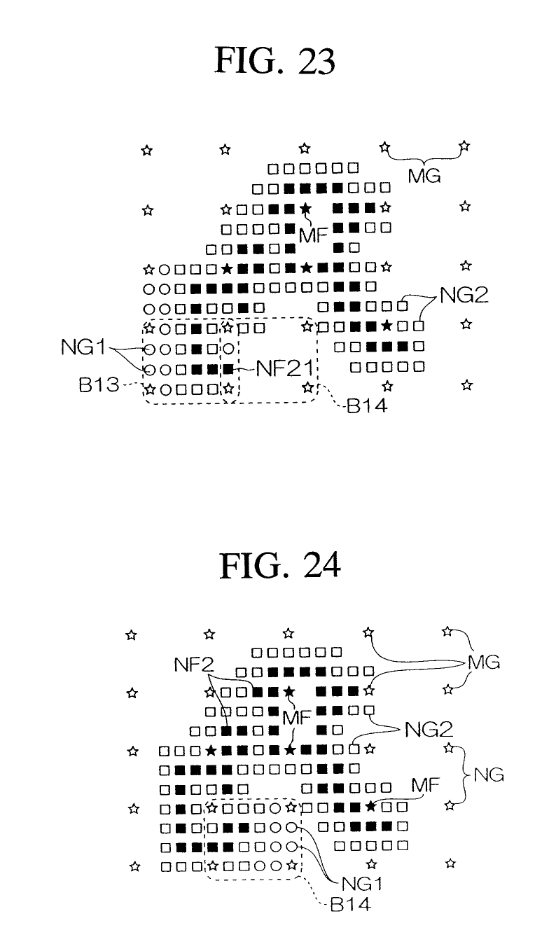

Here, in FIG. 22 and also in FIGS. 23 through 25 which will be referred to hereinafter, the stars denote the vertices of the blocks. And, among these, those white stars denote those vertices MG for which pass decisions have been arrived at, while those black stars denote those vertices MF for which fail decisions have been arrived at. Furthermore, the circles denote those test points for which the test results are the same as those for all the adjacent test points (i.e., test points other than variant points in the block for which decisions have been made).

Among these, those white circles denote those test points NG1 for which pass decisions were arrived at, while those black circles denote those test points NF1 for which fail decisions were arrived at.

Yet further, the squares denote those test points for which the test results are not the same as those for all the adjacent test points (i.e., test points corresponding to variant points in the block for which decisions have been made).

Among these, those white squares denote those test points NG2 for which pass decisions were taken, while those black squares denote those test points NF2 for which fail decisions were taken.

Next, in the step S7, the control section 1, for the upper, lower, and left and right edge regions of the complete testing blocks, if in these edge regions there exists an edge region for which the test result of a test point (including the vertices of the block) is different from those at other test points to which this test point is adjacent, in other words, if in this edge region there exists some edge region which has a test point at which the test result is a pass while the test result at another test point which is adjacent to this test point is a fail, picks out the block which has this edge region mutually in common therewith as another block for which testing is to be performed at all of the test points within it.

Thus, considering the lower edge region of the block B9 in FIG. 22, since a fail decision has been taken at the test point NF20 while a pass decision has been taken at another test point in this edge region which is adjacent to this test point NF20, the control section 1 decides that this edge region is an edge region which has a test point for which the test result differs from the test result at adjacent test points, and it therefore newly picks out the block B13 which has this edge region in common with this block B9 as a fresh complete testing block; and then the flow of control proceeds to the step S8.

Next, in the step S8, as shown in FIG. 23, via the test section 5, the control section 1 performs pass/fail decisions for all the test points in this block B13 which has been newly designated as this fresh testing block, for all the combinations of the parameters within this block. At this time, the control section 1 controls the data for SHMOO plot display so as to display, among the test points which are present in the test range of the SHMOO plot for which testing has been completed, only those test points N which have been understood to be located at the border where the test result changes, as well as the vertices M.

And then the flow of control of the control section 1 progresses to the step S9.

Next, in this step S9, the control section 1 makes a decision, for each edge region of the block B13 which has just been tested, as to whether or not any edge regions have newly been detected which contain test points for which the test results are different from the test results at adjacent test points.

Since in this case the result of this decision is that, in the right side edge region of the block B13, the test result made by the control section 1 for the test point NF21 was a fail decision, while for another adjacent test point the test result was a pass decision, therefore the flow of control is returned to the step S7.

Next, in the step S7, the control section 1 decides that this right side edge region for the block B13 which has been detected is an edge region containing a test point for which the test result is different from a test result at an adjacent test point, and picks out the block B14 which has this edge region in common with the block B13 as another fresh complete testing block.

And, in the step S8, the control section 1 performs pass/fail decisions via the test section 5 for all the test points in this block B14 which has newly become a complete testing block, for all the combinations of parameters in the block, as shown in FIG. 24.

As described above, the control section 1 repeatedly performs the processing of the steps S7 through S9, until, among all the upper, lower, and left and right edge regions of all of the blocks, no edge region is detected in which the test result for any test point (including the vertices) is different from the test result for another adjacent test point.

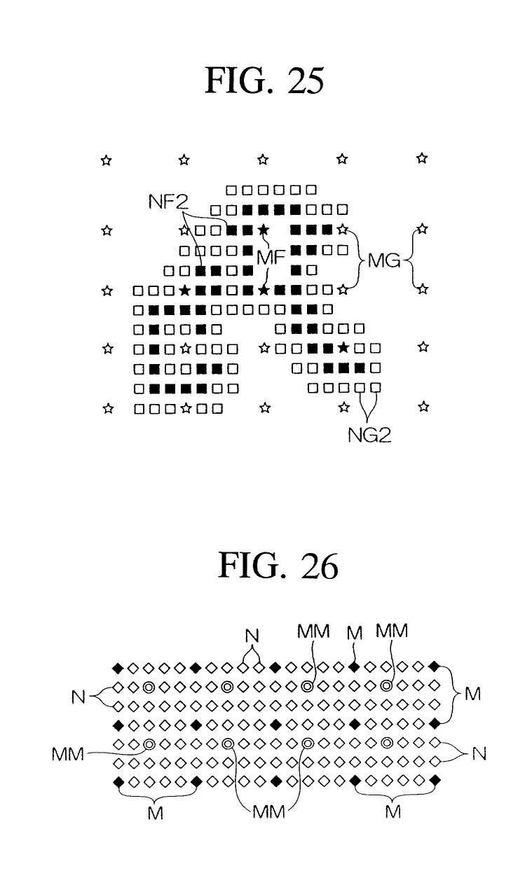

And if, among all the upper, lower, and left and right edge regions of all of the blocks, no edge region has been detected in which the test result for any test point (including the vertices) is different from the test result for another adjacent test point, then the control section 1 outputs the SHMOO plot shown in FIG. 25 from the output section 6 (a CRT or a printer or the like).

On the other hand, if in the step S5 it is decided that all of the patterns of the vertices of the blocks which have been tested either match pattern #1 shown in FIG. 5 or pattern #2 shown in FIG. 6, then the control section 1 returns the flow of control to the step S1, and shifts the position for forming the blocks in the range of the SHMOO plot, and then again starts the processing of the steps S2 through S9 described above.

If as shown in FIG. 26 the starting block is, for example, delimited by the vertices M (the black rhombuses), then the position to which these vertices are shifted is determined as follows. That is, since the plotting interval for the vertices M in the X axis direction is 5 steps through the test points N (as shown by the white rhombuses), therefore the control section 1 shifts the test points in the X axis direction by half this plotting interval—exactly, by rounding down—i.e. by two steps (5/2=2). And, in the same manner, since the plotting interval for the vertices M in the Y axis direction is 3 steps through the test points N, therefore the control section 1 shifts the test points in the Y axis direction by half this plotting interval, rounded down, i.e. by one step (3/2=1). By doing this, the control section 1 forms blocks as defined by the new vertices MM shown by the double circles.

In other words, the control section 1 resets the positions of the blocks so that the vertices of the new blocks fall approximately in the centers of the blocks which were previously defined last time, and then again performs testing via the test section 5. That is to say, here, it performs testing (pass/fail decision) for the test points which are shown in FIG. 26 by the double circles, while it does not perform testing (pass/fail decision) for the test points which are shown in FIG. 26 by the white rhombuses or by the black rhombuses.

Since as described above it is made possible, according to this preferred embodiment of the present invention, to derive the points where the pass/fail test result changes, which is required for the SHMOO plot, while not performing testing for all of the test points, accordingly it becomes possible to output the SHMOO plot at higher speed.

Taking the SHMOO plot shown in FIG. 25 as an example, if pass/fail decisions were made for all the test points, there would be 273 test points in total; while by contrast, with the method of utilizing patterns of this preferred embodiment, the number of test points is reduced to only 227. As a result, it has become possible to increase the speed of circuit testing by 20%.

Although the present invention has been described above in terms of a particular preferred embodiment thereof, and with reference to the drawings, in practice it is not to be considered as being limited by any of the details of the shown embodiment or of the drawings; various alterations may be made in the details of implementation of the present invention, as long as no departure takes place from the range of its gist.

What is claimed is:

1. An IC test device, comprising:
a block grouping section which divides test points within a testing range of a SHMOO plot which is made up from combinations of parameters utilized for IC testing into a plurality of blocks;
a testing section which performs pass/fail decisions for designated test points;
a block pick out section which, along with causing pass/fail decisions to be performed by said testing section for the test points which correspond to the vertices of said blocks, picks out those blocks for which the test results vary between the vertices as complete testing blocks for which testing is to be done at all the test points included in them, based upon patterns of test results which have been obtained by said decisions, and moreover picks out blocks which have in common an edge region which includes vertices for which the test results differ as complete testing blocks, and causes pass/fail decisions to be performed by said testing section for all the test points within said complete testing blocks; and:
a SHMOO plot production section which produces said SHMOO plot based upon results of pass/fail decisions performed by said testing section.

2. An IC test device according to claim 1, further comprising an edge region pick out section which, among the edge regions of said complete testing blocks for which pass/fail decisions have been made by said testing section, detects those edge regions which include mutually adjacent test points, including said vertices, at which the test results differ, and newly picks out those blocks which have said edge regions in common as said complete testing blocks.

3. An IC test device according to claim 1, wherein said SHMOO plot production section produces, as said SHMOO plot, said vertices, and, at the boundary between a region of test points at which pass decisions have been made and a region of test points at which fail decisions have been made, mutually adjacent pairs of a test point at which a pass decision has been made and a test point at which a fail decision has been made.

4. An IC test method, comprising the steps of:
a block grouping step, which divides test points within a testing range of a SHMOO plot which is made up from combinations of parameters utilized for IC testing into a plurality of blocks;
a first picking out step, which performs pass/fail decisions for the test points which correspond to the vertices of said blocks, and picks out those blocks for which the test results vary between the vertices as complete testing blocks for which testing is to be done at all the test points included in them, based upon patterns of test results which have been obtained by said decisions;
a second picking out step, which picks out blocks which have in common an edge region which includes vertices for which the test results differ as complete testing blocks;
a decision step, which performs pass/fail decisions for all the test points in said complete testing blocks; and:
a SHMOO plot production step, which produces said SHMOO plot based upon said pass/fail decision results.

5. An IC test method according to claim 4, further comprising a third picking out step which, among the edge regions of said complete testing blocks for which pass/fail decisions have been made by said decision step, detects those edge regions which include mutually adjacent test points, including said vertices, at which the test results differ, and newly picks out those blocks which have said edge regions in common as said complete testing blocks.

6. An IC test method according to claim 4, wherein, in said first pick out step, the picking out of complete testing blocks is performed by comparing the patterns of the test results which have been obtained from the pass/fail decisions performed at the vertices of said blocks, with pass/fail patterns which are set in advance.

7. An IC test method according to claim 4, wherein, when it has been detected by said first picking out step that the test results are the same between the vertices for all the blocks, in said block grouping step, a different block grouping is performed from the block grouping the previous time.

8. An IC test method according to claim 7, wherein the new block grouping is performed so as to position the vertices of the blocks which are obtained by this new block grouping in the vicinities of the centers of the blocks which were obtained by the block grouping the previous time.

9. An IC test method according to claim 4, wherein said SHMOO plot production step produces, as said SHMOO plot, said vertices, and, at the boundary between a region of test points at which pass decisions have been made and a region of test points at which fail decisions have been made, mutually adjacent pairs of a test point at which a pass decision has been made and a test point at which a fail decision has been made.
